(19) United States
(12) Patent Application Publication
(10) Pub. No.: US 2009/0019334 A1
(43) Pub. Date: Jan. 15, 2009

(54) ERROR CORRECTION SYSTEM USING CONCATENATED CODES

(76) Inventors: Martin Tomlinson, Totnes (GB); Marcel Adrian Ambroze, Plymouth (GB); Cen Jung Tjhai, Plymouth (GB); Mohammed Zaki Ahmed, Plymouth (GB)

Correspondence Address: Martin Tomlinson, The Coach House, Tristford, Harberton, Totnes, TQ9 7RZ, GB

(21) Appl. No.: 11/775,598

(22) Filed: Jul. 10, 2007

(51) Int. Cl. H03M 13/05

(52) U.S. Cl. 714/755; 714/E11.03

(57) ABSTRACT

This invention provides an error correction system whereby codes, including codes known to be optimum, may be concatenated together so that a longer code is produced which may be decoded by decoding the individual codes using any type of error correcting decoder including list decoders, Dorsch decoders in particular, and iterative decoders. The concatenated code consists of one or more codes having replicated codewords to which are added codewords from one or more other codes. The code construction is utilised in the receiver with a decoder that firstly decodes one or more individual codewords from a received vector. The detected codewords from this first decoding are used to undo the code concatenation within the received vector to allow the replicated codewords to be decoded. Examples of the performance benefits of the invention in comparison to the well known state of the art coding arrangement of LDPC codes, and turbo codes using iterative decoders are given for (256,128) and (512,256) codes.

### FIELD OF THE INVENTION

The field of the invention is digital communication systems using forward error correction coding.

### BACKGROUND TO THE INVENTION

This invention relates to digital communications using a communications medium such as wireless where each received packet is subject to noise and/or interference causing errors in some of the received symbols. Typically Forward Error Correction (FEC) is provided using convolutional codes, turbo codes, LDPC codes or algebraic block codes and at the receiver an error correction decoder is used to correct any transmission errors. This invention provides an error correction system which has improved performance over the existing state of the art, for a given code rate and code length.

### BRIEF SUMMARY OF THE INVENTION

The invention uses an error correcting code construction that consists of one or more codes having replicated codewords to which are added codewords from one or more other codes to form a concatenated code. This code construction is utilised in the receiver with a decoder that firstly decodes one or more individual codewords from a received vector. The detected codewords from this first decoding are used to undo the code concatenation within the received vector to allow the replicated codewords to be decoded. The output from the overall decoder of the concatenated code consists of the information symbols from the first decoder followed by the the information symbols from the second stage decoder. In other embodiments of the invention multiple codewords are replicated and added to the codewords from other codes so that the concatenated code consists of several shorter codewords which are decoded first and the decoded codewords used to decode the remaining codewords. In further embodiments of the invention the replicated codewords are themselves concatenated codewords constructed according to the invention and correspondingly the receiver uses more than two stages of decoding.

With suitable modifications, any type of error correction decoder may be utilised by the invention including iterative decoders, Viterbi decoders, list decoders, and ordered reliability decoders, and in particular decoders known as Dorsch decoders. For a given code rate it is well known that longer codes have potentially better performance than shorter codes, but implementation of an efficient decoder is more difficult for longer codes. The invention provides a means whereby several decoders for short codes may be used together to implement an efficient decoder for a long code.

### BRIEF SUMMARY OF THE DRAWINGS

FIG. 1 shows the generic structure of the concatenated codeword in one embodiment of the invention in which the codeword from one error correcting code is replicated and added to the codeword from another error correcting code.

FIG. 2 shows the system for encoding the concatenated codeword format shown in FIG. 1 with the encoding of the first codeword which is replicated and added to the codeword output from a second encoder using a different error correcting code. The juxtaposition of the two codewords forms the codeword of the concatenated code and the symbols of this codeword are mapped to transmission symbols suitable for transmitting through a communications channel.

FIG. 3 shows the decoder corresponding to the encoder shown in FIG. 2 and features for each received vector, buffering of the received vector, soft decision metric calculation, decoding of the individual codeword which was not replicated, followed by remapping, soft metric combining prior to decoding of the replicated individual codeword and the output of k₁+k₂ information symbols.

FIG. 4 shows the generic structure of the concatenated codeword in another embodiment of the invention in which the codeword from one error correcting code is replicated and added to two codewords from one or more other error correcting codes.

FIG. 5 shows shows the generic structure of the concatenated codeword in a further embodiment of the invention in which the codeword from one error correcting code is replicated and added to the codeword from another error correcting code and the resulting codeword is also replicated and added to the codeword from a third error correcting code.

FIG. 6 shows shows the generic structure of the concatenated codeword in a further embodiment of the invention in which the concatenated codeword with the format shown in FIG. 1 is replicated and added to the codeword from another error correcting code.

FIG. 7 shows the comparative frame error rate performance of the embodiment of the invention corresponding to the transmitted codeword format shown in FIG. 1. The concatenated code is a (256,129,24) binary code and it is compared to an optimised LDPC (256,128,12) binary code arrangement and an optimised turbo (256,128,15) binary code arrangement.

FIG. 8 shows the comparative frame error rate performance of the embodiment of the invention corresponding to the transmitted codeword format shown in FIG. 4. The concatenated code is a (512,256,32) binary code and it is compared to an optimised LDPC (512,256,14) binary code arrangement and an optimised turbo (512,256,18) binary code arrangement.

### DETAILED DESCRIPTION OF THE DRAWINGS

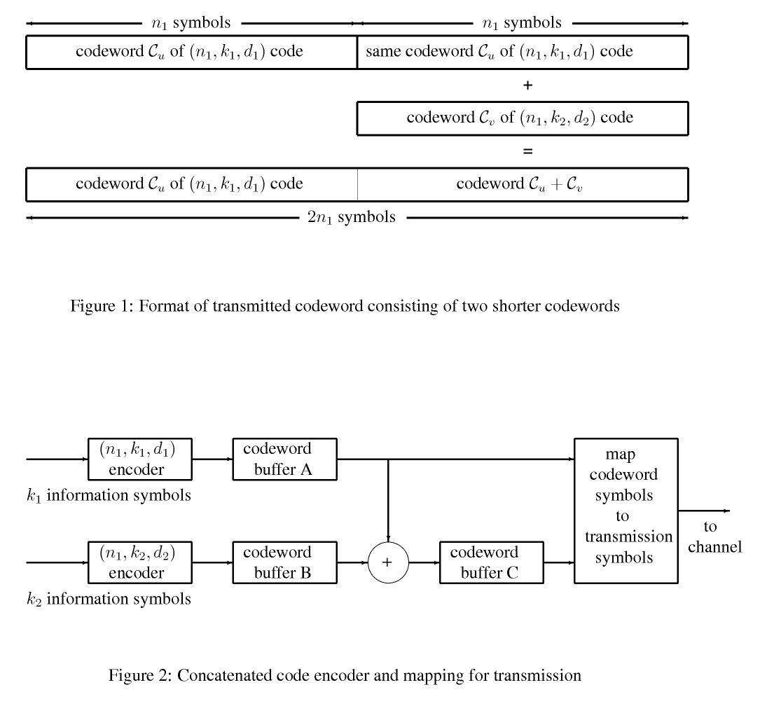

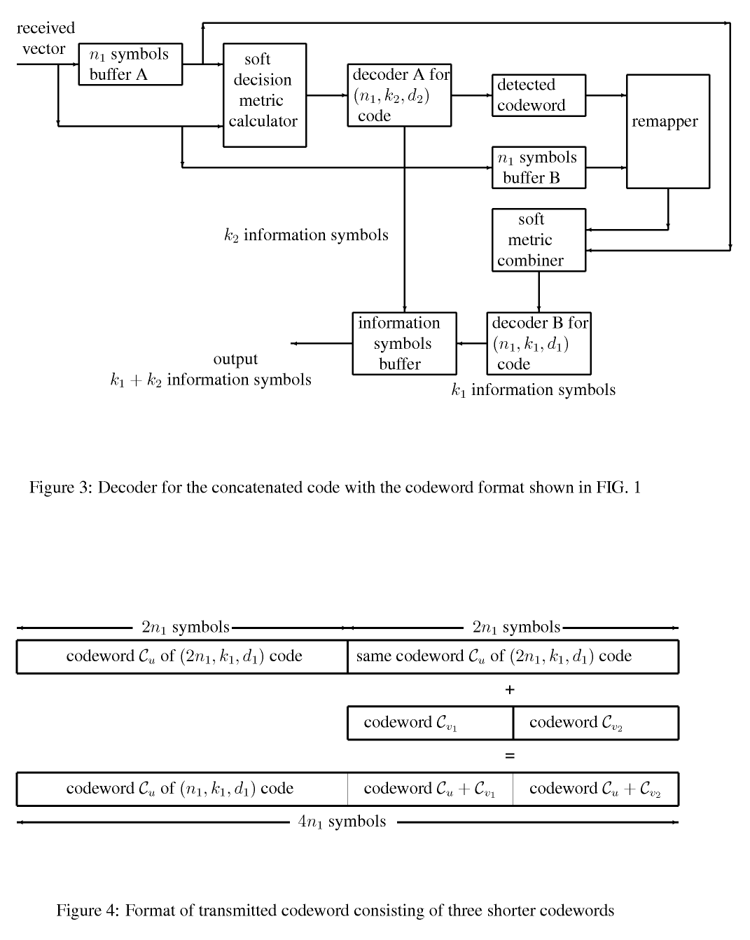

FIG. 1 shows the generic structure of the transmitted signal in one embodiment of the invention in which the codeword of length n₁ from code u, denoted as Cᵤ is followed by a codeword comprising the sum of the same codeword and another codeword from code v, denoted as Cᵥ to form a codeword denoted as C_{cat} of length 2n₁. This code construction is well known as the |u|u+v| code construction documented for example in the text-book by MacWilliams and N. J. A. Sloane, The Theory of Error Correcting Codes, North Holland, 1977. The addition is carried out symbol by symbol using Galois Field arithemetic rules of GF(q). Following the notation in MacWilliams and N. J. A. Sloane if code u is an (n₁, k₁, d₁) code with k₁ information symbols and Hamming distance d₁ and code v is an (n₁, k₂, d₂) code with k₂ information symbols and Hamming distance d₂, the concatenated code C_{cat} is an (2n₁, k₁+k₂, d₃) code with Hamming distance d₃ equal to the smaller of 2×d₁ and d₂.

Prior to transmission, symbols from the concatenated codeword are mapped to signal constellation points in order to maximise the Euclidean distance between transmitted symbols in keeping with current practice. For example see the text book by Professor J. Proakis Digital Communications, McGraw-Hill, 1997. The mapped concatenated codeword is denoted as χ_{cat} and is given by

χ_{cat}=|χᵤ|χᵤ₊ᵥ|=|χᵤ|χ_{w}| (1)

where χ_{w} is used to represent χᵤ₊ᵥ

χ_{cat} consists of 2×n₁ symbols and the first n₁ symbols are the n₁ symbols of χᵤ and the second n₁ symbols are the n₁ symbols resulting from mapping of the symbols resulting from the summation, symbol by symbol, of the n₁ symbols of Cᵤ and the n₁ symbols of codeword Cᵥ.

The encoding system to produce the concatenated codeword format shown in FIG. 1 is shown in FIG. 2. For each concatenated codeword, k₁ information symbols are input to the encoder for the (n₁, k₁, d₁) code and n₁ symbols are produced at the output of the encoder and are stored in the codeword buffer A as shown in FIG. 2. Additionally for each concatenated codeword, k₂ information symbols are input to the encoder for the (n₁, k₂, d₂) code and n₁ symbols are produced at the output and are stored in the codeword buffer B as shown in FIG. 2. The encoded symbols output from the codeword buffer A are added symbol by symbol to the encoded symbols output from the codeword buffer B and the results are stored in codeword buffer C. The codeword stored in codeword buffer A is Cᵤ as depicted in FIG. 1 and the codeword stored in codeword buffer C is Cᵤ+Cᵥ as also depicted in FIG. 1. The encoded symbols output from the codeword buffer A are mapped to transmission symbols and transmitted to the channel and these are followed sequentially by the symbols output from the codeword buffer C which are also mapped to transmission symbols and transmitted to the channel as shown in FIG. 2.

After transmission through the communications medium each concatenated mapped codeword is received as the received vector, denoted as R_{cat} and given by

R_{cat}=|Rᵤ|Rᵤ₊ᵥ|=|Rᵤ|R_{w}| (2)

In this embodiment of the invention codeword Cᵥ is decoded first as shown in FIG. 3. It is possible by comparing the received samples Rᵤ with the received samples Rᵤ₊ᵥ, that the a priori log likelihoods of the symbols of Rᵥ may be determined since it is clear that the difference between the respective samples, in the absence of noise and distortion, is attributable to Cᵥ. This is done in the invention by the soft decision metric calculator shown in FIG. 3.

To simplify the description, without loss of generality, binary codeword symbols are considered with values which are either 0 or 1. The i^{th} transmitted sample Xᵤ_{ᵢ}=(−1)^{Cu}^{ᵢ} and the n₁+i^{th} transmitted sample Xᵤ_{ᵢ}₊ᵥ_{ᵢ}=(−1)^{Cu}^{ᵢ}×(−1)^{Cv}^{ᵢ}. It is apparent that Xᵥ_{ᵢ} and Cᵥ_{ᵢ} may be derived from Xᵤ_{ᵢ} and Xᵥ_{ᵢ}₊ᵥ_{ᵢ}.

An estimate of Xᵥ_{ᵢ} and Cᵥ_{ᵢ} may be derived from Rᵤ_{ᵢ} and Rᵤ_{ᵢ}₊ᵥ_{ᵢ}. Firstly:

Xᵥ_{ᵢ}=Xᵤ_{ᵢ}×Xᵤ_{ᵢ}₊ᵥ_{ᵢ}=(−1)^{Cu}^{ᵢ}×(−1)^{Cu}^{ᵢ}×(−1)^{Cv}^{ᵢ}=(−1)^{Cv}^{ᵢ} (3)

Secondly, in the absence of distortion and with Gaussian distributed additive noise with standard deviation σ, and normalised signal power, the log likelihood that Cᵥ_{ᵢ}=0, L_{log} (Cᵥ_{ᵢ}=0) is given by

$${L}_{log} ( {C}_{{v}_{i}} = 0 ) = log [ cosh ( \frac{{R}_{{u}_{i}} + {R}_{{u}_{i} + {v}_{i}}}{{σ}^{2}} ) ] - log [ cosh ( \frac{{R}_{{u}_{i}} + {R}_{{u}_{i} + {v}_{i}}}{{σ}^{2}} ) ] \qquad ( 4 )$$

The soft decision metric calculator shown in FIG. 3 calculates these log likelihoods according to equation (4) and these are input to the decoder A shown in FIG. 3. The decoder A determines the most likely codeword C_{\hat{v}} of the (n₁, k₂, d₂) code. With the knowledge of the detected codeword, C_{\hat{v}}, the received samples Rᵤ₊ᵥ, which are stored in the n₁ symbols buffer B, are remapped to form R_{û} by multiplying Rᵤ₊ᵥ by χ_{\hat{v}}.

R_{û}=Rᵤ₊ᵥ×χ_{\hat{v}} (5)

This remapping function is provided by the remapper shown in FIG. 3. The output of the remapper is R_{û}. If the decoder is correct C_{\hat{v}}=Cᵥ and there are now two independent received versions of the transmitted, mapped codeword Cᵤ, R_{û} and the original received Rᵤ. Both of these are input to the soft metric combiner shown in FIG. 3, R_{û} from the output of the remapper and Rᵤ from the output of the n₁ symbols buffer A.

The soft metric combiner calculates the log likelihood of each bit of Cᵤ, Cᵤ_{ᵢ} from the sum of the individual log likelihoods:

$${L}_{log} ( {C}_{{u}_{i}} = 0 ) = \frac{2 {R}_{{u}_{i}}}{{σ}^{2}} + \frac{2 {R}_{{\hat{u}}_{i}}}{{σ}^{2}} \qquad ( 6 )$$

These log likelihood values, L_{log}(Cᵤ_{ᵢ}=0), output from the soft metric combiner shown in FIG. 3 are input to the decoder B. The output of Decoder B is the k₁ information bits of the detected codeword C_{û} of the (n₁, k₁, d₁) code and these are input to the information symbols buffer shown in FIG. 3. The other input to the information symbols buffer is the k₂ information bits of the detected codeword C_{\hat{v}} of the (n₁, k₂, d₂) code provided at the output of decoder A. The output of the information symbols buffer, for each received vector, are the k₁+k₂ information bits which were originally encoded, provided both decoders A and B are correct.

In a further embodiment of the invention FIG. 4 shows the format of a concatenated codeword of length 4×n₁ symbols consisting of three shorter codewords. The codeword of length 2×n₁ from a (2n₁, k₁, d₁), code a, denoted as Cᵤ is replicated as shown in FIG. 4. The first half of the replicated codeword, Cᵤ, is added to the codeword Cᵥ₁ and the second half of the replicated codeword, Cᵤ, is added to the codeword Cᵥ₂ as shown in FIG. 4. Each codeword Cᵥ₁ and Cᵥ₂ is the result of encoding k₂ information symbols using code v, a (n₁, k₂, d₂) code. The concatenated codeword that results, C_{cat}, is from a (4n₁, k₁+2k₂, d₃) concatenated code where d₃ is the smaller of 2_{d1} or d₂.

The decoder for the concatenated code with codeword format shown in FIG. 4 is similar to the decoder shown in FIG. 3 except that following soft decision metric calculation each of the two codewords Cᵥ₁ and Cᵥ₂ are decoded independently. With the knowledge of the detected codewords, C_{\hat{v}1} and C_{\hat{v}2}, the received samples Rᵤ₊ᵥ₁, which are buffered, are remapped to form the first n₁ symbols of R_{û} by multiplying Rᵤ₊ᵥ₁ by χ_{\hat{v}1} and the second n₁ symbols of R_{û} are obtained by multiplying Rᵤ₊ᵥ₂ by χ_{\hat{v}2}. The two independent received versions of the transmitted, mapped codeword Cᵤ, R_{û} and the original received Rᵤ are input to a soft metric combiner prior to decoding the codeword C_{û}.

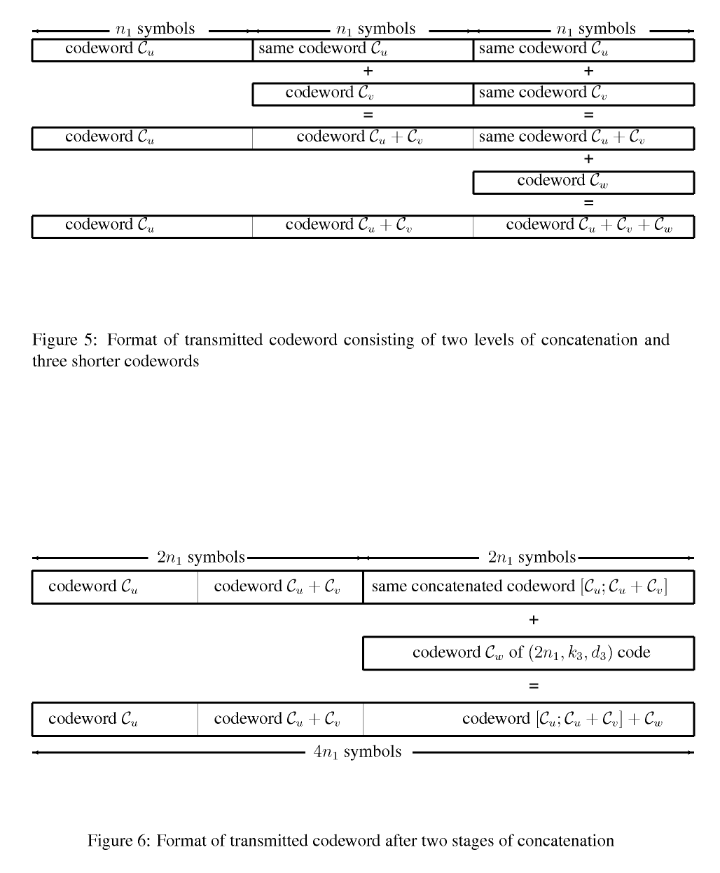

In a further embodiment of the invention FIG. 5 shows the format of a concatenated codeword of length 3×n₁ symbols. The concatenated codeword is the result of three layers of concatenation. A codeword of length n₁ from a (n₁, k₁, d₁), code a, denoted as Cᵤ is replicated twice as shown in FIG. 5. A second codeword of length n₁ from a (n₁, k₂, d₂), code v, denoted as Cᵥ is replicated and each of these two codewords is added to the two replicated codewords Cᵤ as shown in FIG. 5. A third codeword of length n₁ from a (n₁, k₃, d₃), code w, denoted as C_{w} is added to the codeword summation Cᵤ+Cᵥ as shown in FIG. 5. The concatenated codeword that results, C_{cat}, is from a (3n₁, k₁+k₂+k₃, d₄) concatenated code where d₄ is the smallest of 3d₁ or 2d₂ or d₃.

The decoder with this embodiment of the invention, that is, the three layered concatenated code with codeword format shown in FIG. 5 uses similar signal processing to the decoder shown in FIG. 3 with changes corresponding to the three layers of concatenation. The codeword C_{ŵ} is decoded first following soft decision metric calculation using the Rᵤ₊ᵥ and R_{u+v+w} sections of the received vector. The detected codeword C_{ŵ} is used to obtain two independent received versions of the transmitted, mapped result of the two codewords summation Cᵤ₊ᵥ, Rᵤ₊ᵥ and the original received Rᵤ₊ᵥ. These are input to a soft metric combiner and the output is input to the soft decision metric calculation together with Rᵤ, prior to decoding of codeword C_{\hat{v}}. With the knowledge of codeword C_{\hat{v}}, remapping and soft metric combining is carried out prior to the decoding of codeword C_{û}.

In a further embodiment of the invention, FIG. 6 shows the format of a concatenated codeword of length 4×n₁ symbols. The concatenated codeword is the result of three layers of concatenation. A concatenated codeword with the format shown in FIG. 1 is replicated and added to a codeword, C_{ŵ}, of length 2n₁ symbols from a (2n₁, k₃, d₃) code to form a codeword of an overall concatenated code having parameters 4n₁, k₁+k₂+k₃, d₄) where d₄ is equal to the smallest of 4d₁, 2d₂, or d₃.

The decoder with this embodiment of the invention, that is, the three layered concatenated code with codeword format shown in FIG. 6 is similar to the decoder described in paragraph [0027]. Codeword C_{ŵ} is detected first following soft decision metric calculation using the Rᵤ and Rᵤ₊ᵥ sections of the received vector as one input and the R_{u+w} and R_{u+v+w} sections of the received vector as the other input. The detected codeword C_{ŵ} is used to obtain two independent received versions of the concatenated codeword of length 2n₁ symbols with format equal to that of FIG. 1. Accordingly, following soft metric combining of the two independent received versions of the concatenated codeword of length 2n₁ symbols, a vector of length equal to 2n₁ symbols is obtained which may be input to the concatenated code decoder shown in FIG. 3. This decoder provides at its output the k₁+k₂ detected information symbols which together with the k₃ information symbols already detected provides the complete detected output of the overall three layer concatenated code.

Any type of code, binary or non binary, LDPC, Turbo or Algebraic constructed code, may be used by the invention. Any corresponding type of decoder, for example an iterative decoder or a list decoder may be used. As an illustration of this, Decoder A and Decoder B shown in FIG. 3 do not have to be the same type of decoder.

There are particular advantages in using the invention for a type of list decoder known as a Dorsch decoder because as shown in IET Communications Vol. 1, issue 3, pp. 479-488, June 2007 by Tomlinson et. al. the Dorsch decoder may realise close to maximum likelihood decoding, the theoretically best type of decoding, with reasonable complexity of the decoder. The complexity increases exponentially with codelength. Both decoder A and decoder B shown in FIG. 3 operate on n₁ received samples and may realise close to maximum likelihood decoding with reasonable complexity even though the concatenated codelength is 2×n₁ symbols and the total number of received samples is 2×n₁ samples. Using a single Dorsch decoder to decode the 2×n₁ samples of the concatenated code directly will usually result in non maximum likelihood performance unless the list of codewords evaluated for each received vector is very long. For example a Dorsch decoder with moderate complexity, typically will process 100,000 codewords for each received vector and realise near maximum likelihood performance. Doubling the codelength will require typically in excess of 100,000,000 codewords to be processed for each received vector if near maximum likelihood performance is to be maintained.

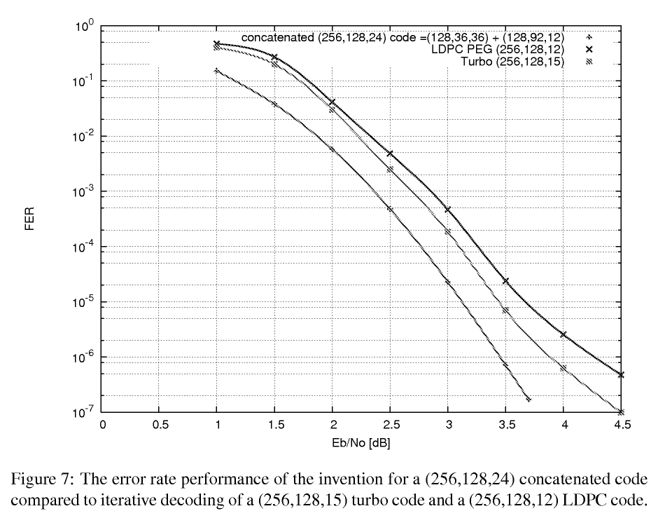

An example of the performance achieved by the invention is shown in FIG. 7 for the concatenated codeword format shown in FIG. 1. The encoder used is the same as that shown in FIG. 2 and the concatenated code decoder is the same as that shown in FIG. 3. The results were obtained by computer simulation of the invention and the well known digital communications channel using Quaternary Phase Shift Keying (QPSK) modulation and featuring Additive White Gaussian Noise (AWGN), a description of which is contained in many digital communications text-books, for example Digital Communications, McGraw-Hill, 1997 by Professor J. Proakis. The decoder error rate, the ratio of the number of incorrect codewords output by the decoder to the total number of codewords output by the decoder, is denoted by the Frame Error Rate (FER) and this is plotted against E_{b}/Nₒ, the ratio of the energy per information bit to the noise power spectral density. Binary codes are used and the length of the concatenated code is 256 bits. Code u is the (128,92,12) extended Bose Chaudhuri Hocquenghem (BCH) code described for example in the text-book Error-Correcting Codes, M.I.T. Press, 1961 by Professor W. Wesley Peterson. Code v is the (128,36,36) extended cyclic code, an optimum code described in On binary cyclic codes of odd length from 101 to 127 by D. Schoemaker and M. Wirtz, IEEE Transactions Information Theory, Vol 38, No 2, pp. 56-59, March 1992. The minimum Hamming distance of the concatenated code is 2d₁=24. Both decoder A and decoder B, as shown in FIG. 3, is a Dorsch decoder (a full description of a Dorsch decoder may be found in IET Communications Vol. 1, issue 3, pp. 479-488, June 2007) and for both code u and code v, near maximum likelihood performance is obtained with moderate decoder complexity. For each point plotted in FIG. 7, the number of codewords transmitted was chosen such that were at least 100 codewords decoded in error.

Also shown in FIG. 7 is the performance of codes and decoders designed according to the currently known state of the art in error correction coding that is Low Density Parity Check (LDPC) codes using Belief Propagation (BP) iterative decoding, and Turbo codes with BCJR iterative decoding. These two well known techniques are described in several error correction coding text-books, for example, refer to Error Control Coding by D. J. Costello and Shu Lin, Prentice-Hall, Second edition, 2004. Featured in FIG. 7 is the performance of an optimised Low Density Parity Check (LDPC) (256,128,12) code using BP, iterative decoding and an optimised (256,128,15) Turbo code with iterative decoding. As shown in FIG. 7 both the (256,128,15) Turbo code and the (256,128,12) LDPC code suffer from an error floor for E_{b}/Nₒ values higher than 3.5 dB whilst the invention has a FER performance with no error floor. This is attributable to the significantly higher minimum Hamming distance of the concatenated code used in the invention which is equal to 24 in comparison to 15 for the Turbo code and 12 for the LDPC code. Throughout the entire range of E_{b}/Nₒ values the invention can be seen to outperform the existing state of the art in error correction coding for (256,128) codes.

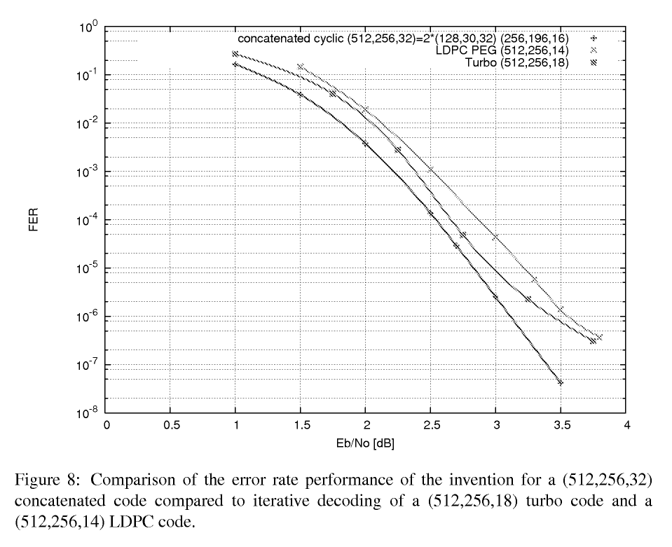

Another example of the performance achieved by the invention is shown in FIG. 8 for the concatenated codeword format which is shown in FIG. 4. As before, the FER results were obtained by computer simulation of the invention for the same digital communications channel using Quaternary Phase Shift Keying (QPSK) modulation and featuring Additive White Gaussian Noise (AWGN). Both codes v₁ and v₂ are the same and equal to a(128,30,32) extended cyclic code and code u is equal to a (256,196,16) extended cyclic code. Featured in FIG. 8 is the performance of an optimised Low Density Parity Check (LDPC) (512,256,14) code using BP iterative decoding and an optimised (512,256,18) Turbo code with iterative decoding. For each point plotted in FIG. 8, the number of codewords transmitted was chosen such that were at least 100 codewords decoded in error. As shown in FIG. 8 both the (512,256,18) Turbo code and the (512,256,14) LDPC code suffer from an error floor for E_{b}/Nₒ values higher than 3.4 dB whilst the invention has a FER performance with no error floor. As before this is attributable to the significantly higher minimum Hamming distance of the concatenated code which is equal to 32 in comparison to 18 for the Turbo code and 14 for the LDPC code. Throughout the entire range of E_{b}/Nₒ values the invention can be seen to outperform the existing state of the art in error correction coding for (512,256) codes.

Although the invention has been described and illustrated in the above description and diagrams, it is understood that this description is by way of example only and that numerous changes and modifications can be made by those skilled in the art without departing from the broad scope of the invention. The applicants' invention should be limited only by the claims.

What is claimed is:

1. A system in which a codeword from one error correcting code is replicated,
and a codeword from another error correcting code is added to the replicated codeword in a concatenated arrangement to form a codeword from a single overall code,
and in which the individual codeword which was added is separately decoded,
and this decoded codeword is used in the decoding of the replicated codeword so that the two decoded individual codewords collectively provide a decoded output codeword for the overall code.

2. A system in which a codeword from one error correcting code is replicated,
and one or more codewords from other error correcting codes are added to each replicated codeword in a concatenated arrangement to form a codeword from a single overall code,
and in which some of the individual codewords are separately decoded,
and these decoded codewords are used in the decoding of the replicated individual codewords so that all of the decoded individual codewords collectively provide a decoded output codeword for the overall code.

3. A system in which codewords from several error correcting codes are replicated,
and codewords from other error correcting codes are added to the replicated codewords in a concatenated arrangement to form a codeword from a single overall code,
and in which some of the individual codewords are separately decoded,
and these decoded codewords are used in the decoding of the replicated individual codewords so that all of the decoded individual codewords collectively provide a decoded output codeword for the overall code.

4. A system according to claim 1 or claim 2 or claim 3 in which any codeword, which is replicated, is itself the result of one or more code concatenations according to claim 1 or claim 2 or claim 3.

5. A system according to claim 1 or claim 2 or claim 3 or claim 4 in which the decoder used to decode one or more of the individual codewords is a list decoder.

6. A system according to claim 1 or claim 2 or claim 3 or claim 4 in which the decoder used to decode one or more of the individual codewords is an ordered reliability decoder known as a Dorsch decoder.

7. A system according to claim 1 or claim 2 or claim 3 or claim 4 in which the decoder used to decode one or more of the individual codewords is an iterative decoder. _
